(19) United States
(12) Patent Application Publication
(10) Pub. No.: US 2009/0027842 A1
(43) Pub. Date: Jan. 29, 2009

(54) DISPLAY DEVICE WITH NAVIGATION CAPABILITY

(75) Inventors: Philip Sandell, Malmo (SE); Magnus U. Nilsson, Vastra Frolunda (SE); Daniel Sundius, Malmo (SE)

Correspondence Address: HARRITY & HARRITY, LLP, 11350 RANDOM HILLS ROAD, SUITE 600, FAIRFAX, VA, 22030, US

(73) Assignee: SONY ERICSSON MOBILE COMMUNICATIONS AB, Lund (SE)

(21) Appl. No.: 11/839,747

(22) Filed: Aug. 16, 2007

Related U.S. Application Data
(60) Provisional application No. 60/952,317, filed on Jul. 27, 2007.

(51) Int. Cl. H05K 5/00; H04B 1/38

(52) U.S. Cl. 361/681; 455/90.3

(57) ABSTRACT

A device may include a display, a component configured to be manipulated in a one dimensional, a two dimensional, or a three dimensional fashion, logic to detect a variable associated with the manipulation, logic to generate a signal corresponding to the detected manipulation, and logic to utilize the signal in the device or output the signal to an external device, where the component includes at least one of the display or one or more keys, and where the component capable of moving in the one dimensional fashion is configured to move in a direction other than a direction substantially perpendicular to a surface of the device that includes the component.

### RELATED APPLICATION

This application claims priority under 35 U.S.C. §119 based on U.S. Provisional Application Ser. No. 60/952,317, filed Jul. 27, 2007, the disclosure of which is incorporated herein by reference.

### BACKGROUND

The proliferation of devices, such as handheld and portable devices, has grown tremendously within the past decade. A majority of these devices include some kind of display to provide a user with visual information. These devices may also include an input device, such as a keypad and/or one or more buttons to allow a user to enter some form of input. However, in some instances, the input device may limit the space available for other components, such as the display. In other instances, the capabilities of the input device may be limited. Accordingly, a device having an alternate approach for providing input and display capabilities may be realized.

### SUMMARY

According to one aspect, a portable device may include a display, a component capable of moving in a one dimensional, a two dimensional, or a three dimensional fashion, logic to detect a variable associated with a movement of the component, logic to generate a signal corresponding to the detected variable, and logic to utilize the signal in the portable device or output the signal to an external device, where the component includes at least one of the display or one or more keys, and where the component capable of moving in the one dimensional fashion is capable of moving in a direction other than a direction substantially perpendicular to a surface of the portable device that includes the component.

Additionally, the portable device may include wireless telephone capability.

Additionally, the portable device may include a flexible member connected to the component to provide maneuverability in the one dimensional, the two dimensional or the three dimensional fashion.

Additionally, the variable may include at least one of force, pressure, motion, position, velocity, or acceleration.

Additionally, the portable device may include at least one of a candybar style, a flip style, a slider style, a jackknife style, a tablet style, a sandwich style, or a combination thereof.

Additionally, the portable device may include logic to disable at least one of the logic to detect, the logic to generate, or the logic to utilize.

Additionally, the logic to utilize the signal may include logic to map the signal to a function associated with an application running on the portable device.

Additionally, the function may include at least one of a cursor function, a selection function, a scrolling function, a turning a page function, a zoom-in function, a zoom-out function, a rotate function, or a resize function.

Additionally, the portable device may include a speaker and a vibration system, where the logic to utilize the signal may include logic to map the signal to at least one of the speaker to output an auditory cue or the vibration system to output a tactile cue.

Additionally, the display may include a touchscreen.

Additionally, where the logic to generate a signal may include logic to compare a value associated with the movement to a threshold value, where when the value exceeds the threshold value, the logic to generate generates the signal.

According to another aspect, a portable device may include a display, a component capable of being manipulated in a one dimensional, a two dimensional, or a three dimensional fashion, logic to detect the manipulation, logic to generate a signal corresponding to the detected manipulation, and logic to associate the signal with a function to be utilized in the portable device or output to an external device, where the component includes at least one of the display or a keypad, and where the component capable of being manipulated in the one dimensional fashion is capable of being manipulated in a direction other than a direction substantially perpendicular to a surface of the portable device that include the component.

Additionally, the logic to detect the manipulation may include logic to detect pressure.

According to still another aspect, a method may include moving in a one dimensional, a two dimensional, or a three dimensional fashion a component of a device having a display, detecting a variable associated with the movement, generating a signal corresponding to the detected variable, and applying the signal to the device or to an external device, where the component include at least one of the display or one or more keys, and where the moving in the one dimensional fashion is moving in a direction other than a direction substantially perpendicular to a surface of the device that includes the component.

Additionally, the detecting the variable may include detecting at least one of force, pressure, motion, position, velocity, or acceleration.

Additionally, the applying the signal to the device may include providing a function that is displayable on the display.

Additionally, the applying the signal to the external device may include providing a function that is displayable on an external display, where a direction associated with the moving of the component corresponds to the function.

Additionally, the generating the signal corresponding to the detected variable may include determining whether a value of the variable associated with the movement of the component exceeds a threshold value.

Additionally, the generating the signal corresponding to the detected variable may include mapping the signal to a function associated with an application running on the device, and displaying the function on the display.

Additionally, the moving in the two dimensional or the three dimensional fashion may include moving the component in a twisting manner.

According to yet another aspect, a device may include means for displaying visual information, means for providing the means for displaying to be movable in a one dimensional, a two dimensional, or a three dimensional fashion, means for detecting a variable associated with a movement of the means for displaying, and means for providing a function that corresponds to the detected movement, where the function is displayable on the means for displaying.

### BRIEF DESCRIPTION OF THE DRAWINGS

The accompanying drawings, which are incorporated in and constitute a part of this specification, illustrate exemplary embodiments described herein and, together with the description, explain these exemplary embodiments. In the drawings:

FIG. 1(a) is a diagram illustrating a front view of exemplary external components of an exemplary device having a display with navigation capability;

FIG. 1(b) is a diagram illustrating a side view of the exemplary device depicted in FIG. 1(a);

FIG. 1(c) is a diagram illustrating a front view of a bottom portion of the exemplary device depicted in FIG. 1(a);

FIG. 1(d) is a diagram illustrating exemplary sensing elements of the exemplary device depicted in FIG. 1(a);

FIG. 1(e) is a diagram illustrating a side view of a top portion of the exemplary device depicted in FIG. 1(a);

FIG. 1(f) is a diagram illustrating a side view of the top portion and bottom portion of the exemplary device depicted in FIG. 1(a);

FIG. 2 is a diagram illustrating exemplary internal components of the exemplary device depicted in FIG. 1(a);

FIG. 3(a)-FIG. 3(l) are diagrams illustrating exemplary movements of the display of the exemplary device depicted in FIG. 1(a);

FIG. 4 is a flow diagram illustrating exemplary operations associated with the exemplary device depicted in FIG. 1(a); and

FIG. 5(a)-FIG. 5(c) are diagrams illustrating exemplary operations associated with the display of the exemplary device depicted in FIG. 1(a).

### DETAILED DESCRIPTION

The following detailed description refers to the accompanying drawings. The same reference numbers in different drawings may identify the same or similar elements. Also, the following description does not limit the invention.

### Overview

Implementations described herein may provide a device with a display. In one implementation, the display may include, for example, a touchscreen. In other implementations, the display may not include, for example, a touchscreen. Additionally, the device may include an input device, such as one or more input buttons and/or a keypad. In other implementations, the device may not include an input device, such as one or more buttons and/or a keypad.

In one exemplary embodiment, the display may have maneuverability in “X”, “Y”, and/or “Z” directions, and/or combinations thereof. For example, the device may include a display capable of being moved by a user in a one dimensional (1D) fashion (e.g. side-to-side), in a two dimensional (2D) fashion (e.g., twisting left-to-right), and/or in a three dimensional (3D) fashion (e.g., twisting right-to-left and down simultaneously).

The device may detect any variable (e.g., force, pressure, position, motion, acceleration velocity, etc.) associated with the movement of the display and translate the detected variable as an input signal. The input signal may be utilized in a variety of different ways. For example, a user may move a cursor through a menu system by moving the display. Additionally, or alternatively, the input signal may be associated with an external device. For example, the input signal may be utilized to control another device, such as a remote control vehicle (e.g., a car, airplane or helicopter) or a security camera. For example, a user may steer a car or point a security camera in a certain direction by moving the display. Additionally, or alternatively, a user may connect the device to an external display, such as a television, when running a game on the device. For example, a user may be able to control a game character by moving the display of the device while the game is displayed on the television. In other examples, the input signal may provide auditory and/or tactile cues to a user of the device. For example, various sounds may be associated with the input signal to indicate to a user that the display is moved in a certain manner (e.g., “Up” or “Down”), or that a particular function has occurred (e.g., “Highlighted”). For example, the device may output an auditory cue through a speaker. In still other examples, the input signal may provide for a vibration to occur that may allow a user of the device, for example, to confirm that the display is moved.

In another exemplary embodiment, the display may be capable of providing navigation capability without being moved. For example, a user may manipulate the display (e.g., applying a force to the display) that does not necessarily result in the display moving. Similarly, the input signal may be utilized within the device and/or external to the device as described herein.

In other implementations, a device may include a display that does not have navigation capability. For example, a device may include an input device that moves and provides a user with navigation capability analogous to a display as described herein. For example, a keypad may be capable of moving in a 1D, 2D, and/or 3D fashion, or any combination thereof, as described herein. Alternatively, a device may include, for example, an input device and a display that move in unison, and provide a user with navigation capability. For example, an input device, such as one or more buttons, and a display, may reside on a top portion of the device. The top portion of the device may move in relation to a bottom portion (e.g., a base) of the device.

Accordingly, as described herein, depending on the configuration of the device, a user with a device having a display may be afforded numerous possibilities for operating the device and/or other devices connected thereto.

### Exemplary Device

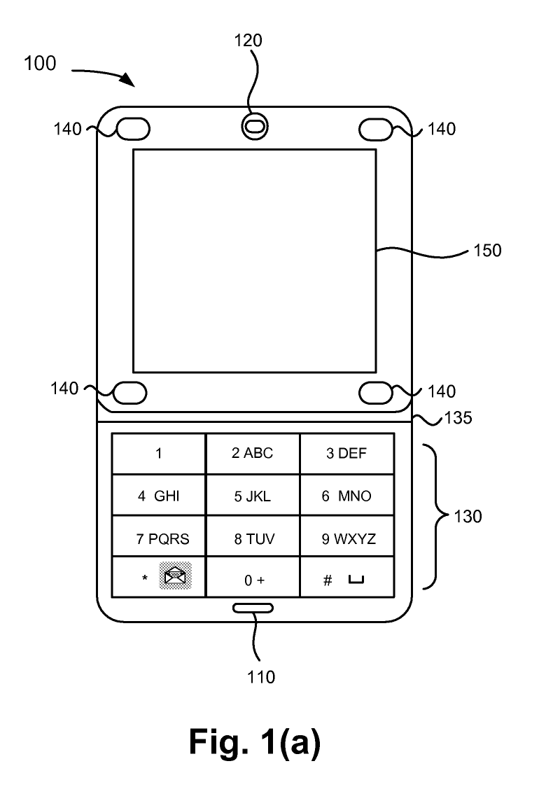

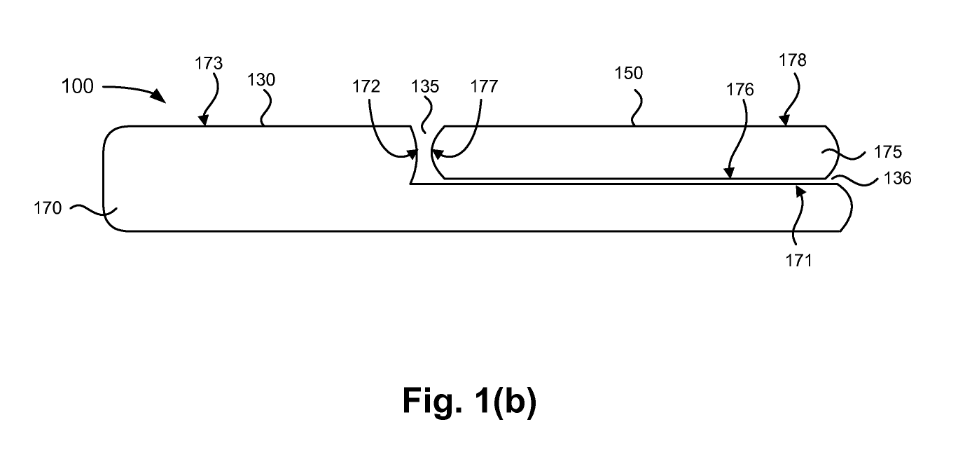

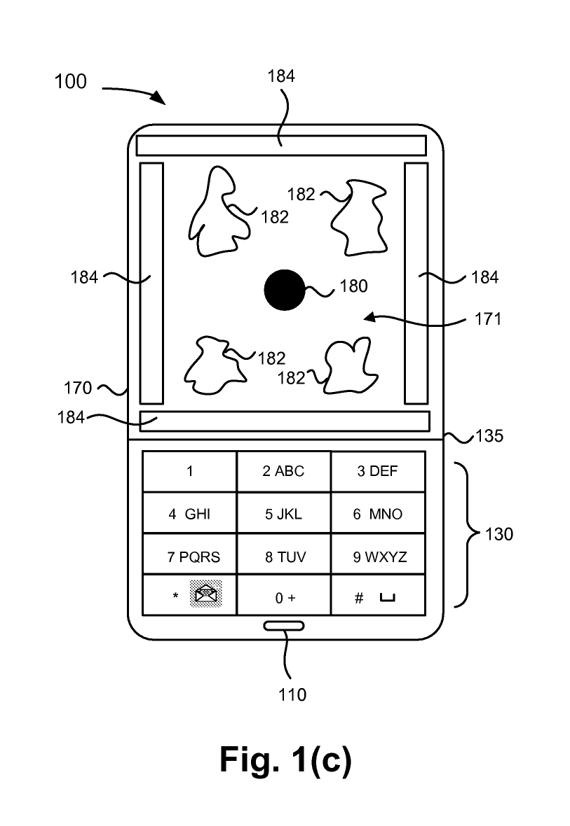

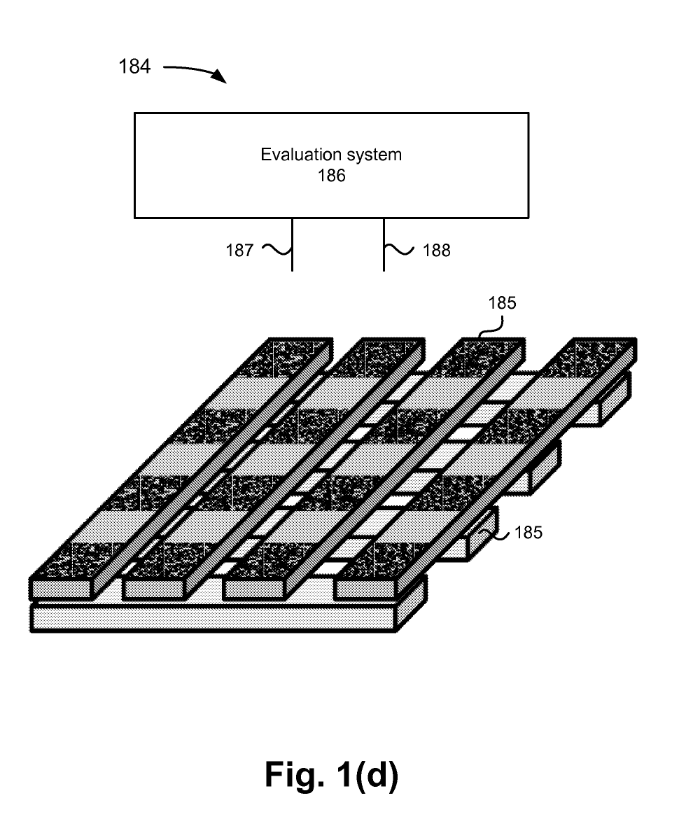

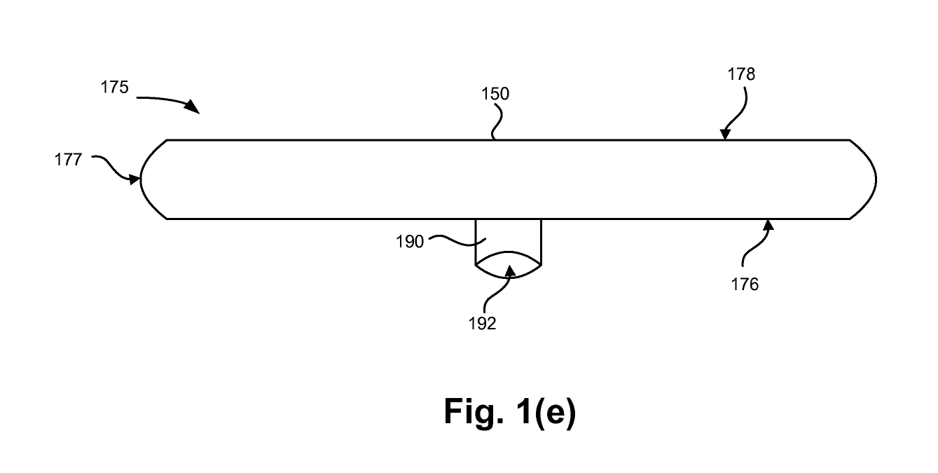

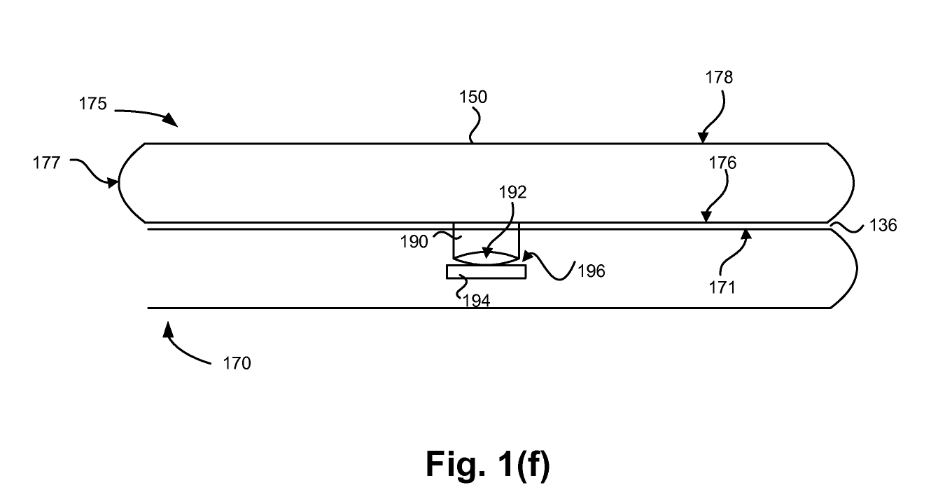

FIG. 1(a) is a diagram illustrating a front view of exemplary external components of an exemplary device having a display with navigation capability. As illustrated in FIG. 1(a), a device 100 may include a microphone 110, a speaker 120, a keypad 130, a space 135, control keys 140, and a display 150.

Microphone 110 may include any component capable of transducing air pressure waves to a corresponding electrical signal. For example, a user may speak into microphone 110 during a telephone call. Speaker 120 may include any component capable of transducing an electrical signal to a corresponding sound wave. For example, a user may listen to music through speaker 120.

Keypad 130 may include any component capable of providing input to device 100. Keypad 130 may include a standard telephone keypad. Keypad 130 may also include one or more special purpose keys. In one implementation, each key of keypad 130 may be, for example, a pushbutton. A user may utilize keypad 130 for entering information, such as text or a phone number, or activating a special function.

Space 135 may be a gap that exists between keypad 130 and display 150 to permit display 150 to be moved in a two dimensional or a three dimensional fashion. Space 135 will be described in greater detail below.

Control keys 140 may include any component capable of providing input to device 100. For example, control keys 140 may include a key that permits a user to cause device 100 to perform one or more operations, such as placing a phone call, playing various media, accessing an application, or providing a select function. In one implementation, control keys 140 may be pushbuttons.

Display 150 may include any component capable of providing visual information. For example, in one implementation, display 150 may be a liquid crystal display (LCD). In another implementation, display 150 may be any one of other display technologies, such as a plasma display panel (PDP), a field emission display (FED), etc. Display 150 may be utilized to display, for example, text, image, and/or video information. Additionally, display 150 may include navigational capability. The navigational capability of display 150 will be described in greater detail below. In other implementations, display 150 may not include navigational capability.

Since device 100 illustrated in FIG. 1(a) is exemplary in nature, device 100 is intended to be broadly interpreted to include any type of electronic device that includes a display, such as display 150. For example, device 100 may include a wireless phone, a personal digital assistant (PDA), a handheld computer, an audio player (e.g., an MP3 player), an audio-visual (AV) player/recorder device (e.g., a DVD player), a portable Global Positioning System (GPS) device, a data organizer, or a game system. In other instances, device 100 may include other types of devices, such as medical devices, military devices, vehicular devices, aircraft devices, etc. Accordingly, although FIG. 1(a) illustrates exemplary external components of device 100, in other implementations, device 100 may contain fewer, different, or additional external components than the external components depicted in FIG. 1(a). For example, in other implementations, device 100 may not include keypad 130. Additionally, or alternatively, one or more components of device 100 may include the capabilities of one or more other components of device 100. For example, display 150 may include an input component, such as a touchscreen. Alternatively, or additionally, for example, keypad 130 may be configured to include navigational capability. Additionally, or alternatively, the external components may be arranged differently than the external components depicted in FIG. 1(a). For example, control keys 140 may not be arranged around a perimeter of display 150.

FIG. 1(b) is a diagram illustrating a side view of exemplary device 100. In addition to the external components previously described, device 100 may include a bottom portion 170 and a top portion 175. Bottom portion 170 may include a top surface 171, a side surface 172, and a top surface 173. Keypad 130 may be located on or in top surface 173 of bottom portion 170. Top portion 175 may include a bottom surface 176, a side surface 177, and a top surface 178. Display 150 may be located on or in top surface 178. Although not illustrated, bottom portion 170 and top portion 175 may each include a housing to protect components contained therein. Space 135 may exist between side surface 172 of bottom portion 170 and side surface 177 of top portion 175. Space 136 may exist between top surface 171 of bottom portion 170 and bottom surface 176 of top portion 175. Spaces 135 and 136 will be discussed in further detail below.

Since device 100 illustrated in FIG. 1(b) is exemplary in nature, device 100 is intended to be broadly interpreted to include numerous configurations. For example, top surface 178 of top portion 175 may include keypad 130, and top surface 173 of bottom portion 170 may include display 150. That is, keypad 130 may include navigational capability and display 150 may not include navigation capability. In other implementations, top portion 175 and bottom portion 170 may be relatively equal in size and shape. For example, top portion 175 may include both keypad 130 and display 150. That is, for example, both keypad 130 and display 150 may include navigational capability.

Additionally, it is to be understood, although device 100 appears to resemble a candybar configuration, other configurations may be implemented. For example, a slider-type configuration, a flip-type configuration, a jackknife-type configuration, a tablet-type configuration, or any combination thereof, may be implemented. In other configurations, device 100 may include a sandwich configuration (e.g., a top and a bottom portion of similar size and shape), where the top portion includes display 150 having navigation capability.

FIG. 1(c) is a diagram illustrating a front view of bottom portion 170 depicted in FIG. 1(b). As illustrated in FIG. 1(c), top surface 171 of bottom portion 170 may include a recess 180, an adhesive 182 and sensing elements 184.

Recess 180 may be a space configured to receive a coupler, as will be described below, which may connect bottom portion 170 and top portion 175. Recess 180 may reside at a center portion of top surface 171, and may be circular in shape. In other implementations, recess 180 may reside at a different portion of top surface 171, at multiple portions of top surface 171, and/or may have a different shape. Recess 180 will be described further below.

Adhesive 182 may include, for example, flexible glue that may be utilized to provide maneuverability of top portion 175 that includes display 150. For example, adhesive 182 may include an RTV (Room Temperature Vulcanized) bonding adhesive (e.g., silicone based) that is stretchable. Adhesive 182 may be synthetic. Adhesive 182 may include, for example additives to improve age, temperature, and light resistances. In other implementations, adhesive 182 may be a different type of flexible adhesive (e.g., an acrylic foam tape adhesive). As illustrated, adhesive 182 may be disposed at various portions of top surface 171. In other implementations, adhesive 182 may be disposed at different portions of top surface 171. Adhesive 182 will be described further below.

Sensing elements 184 may be include any component capable of detecting one or more variables associated with a movement of display 150 in a 1D, 2D, and/or 3D fashion, or any combination thereof. For example, sensing elements 184 may detect force, pressure, position, motion, acceleration velocity, etc. In one implementation, for example, sensing elements 184 may be capacitive sensors strategically placed on top surface 171. The capacitive sensors may include, for example, an array of capacitive pressure sensors capacitors capable of detecting capacitive changes associated with pressure that corresponds to a movement of display 150. Each of the capacitive pressure sensors may include a compressible dielectric matrix that acts like a spring. For example, the dielectric matrix may be a RTV silicone rubber. The selection of materials and design of the capacitive sensor may depend on factors such as sensitivity, hysteresis, and repeatability characteristics, as well as stability and power consumption considerations. In other implementations, the capacitive pressure sensors may be made from non-silicon materials.

FIG. 1(d) is a diagram illustrating sensing elements 184, depicted in FIG. 1(c), according to an exemplary implementation. As illustrated, sensing elements 184 may include among other things, column and row capacitor electrodes 185, an evaluation system 186, power lines 187 and data lines 188. In one implementation, capacitor electrodes 185 may be arranged in an orthogonal manner (e.g., overlapping strips) that allow evaluation system 186 to selectively scan a single column and a single row. Evaluation system 186 may include any logic capable of interpreting data supplied from the capacitive pressure sensor. Logic, as used herein, may include hardware, software, and/or a combination of hardware and software. Evaluation system 186 may include, for example, an application specific integrated circuit (ASIC). Evaluation system 186 may supply power to the capacitive pressure sensors on power lines 187, and may receive data from the capacitive pressure sensors on data lines 188.

In an exemplary operation, when pressure (e.g., from display 150) acts upon a capacitive pressure sensor, the capacitance of that capacitive pressure sensor (i.e., the measuring capacitor) may change. A measuring signal may be output to evaluation system 186 on data lines 188. Evaluation system 186 may determine a movement of display 150 based on the measuring signals from each capacitive pressure sensor.

Referring back to FIG. 1(c), sensing elements 184 are depicted as being arranged along a perimeter of top surface 171. In other implementations, sensing elements 184 may reside on different portions of top surface 171. In one implementation, each of the sensing elements 184 may include evaluation system 186. In such an implementation, each evaluation system 186 may be synchronized with one another in order to determine a movement of display 150. Alternatively, evaluation system 186 may receive data from more than one sensing element 184. Sensing elements 184 will be described further below.

Bottom portion 170 of device 100 may include fewer, additional, and/or different components than the exemplary components depicted in FIG. 1(c). That is, it is to be understood that there are a multitude of possibilities to couple bottom portion 170 and top portion 175 to provide the maneuvering capability of display 150, and to detect one or more variables associated with a movement of display 150.

For example, in other implementations, device 100 and/or bottom portion 170 may not include a space, such as recess 180, to couple bottom portion 170 and top portion 175. Similarly, in other implementations, device 100 and/or bottom portion 170 may not include an adhesive element, such as adhesive 182, to provide for the maneuvering capability of display 150, as described herein. For example, other resilient members, such as spring connectors could be employed. In other implementations, device 100 and/or bottom portion 170 may not include capacitive sensors, such as sensing elements 184, to detect a variable associated with the navigation capability of display 150. For example, sensing elements 184 may include strain gauges, film resistors, piezoresistive pressure sensors, optical sensors, etc. that may detect any variable (e.g., pressure, force, velocity, position, acceleration, motion, etc.) associated with a movement of display 150. Further, sensing elements 184 may include a variety of different types of sensors. For example, sensing elements 184 may include a pressure sensor and a position sensor (e.g., a linear position sensor and/or an angular position sensor).

Additionally, or alternatively, each of sensing elements 184 may not be positioned all on one surface of device 100, as described above. Additionally, or alternatively, while exemplary components have been described in relation to bottom portion 170, in other implementations, top portion 175 may include the exemplary components as described above. Additionally, or alternatively, both bottom portion 170 and top portion 175 may include one or more of these exemplary components as described above.

Additionally, although FIG. 1(d) illustrates exemplary capacitive pressure sensors, in other implementations, sensing elements 184 may include fewer, additional and/or different components. That is, it is to be understood that there are a multitude of possibilities for implementing capacitive pressure sensors.

FIG. 1(e) is a diagram illustrating a side view of top portion 175 depicted in FIG. 1(b). In addition to the components previously described, top portion 175 of device 100 may include a coupler 190 with bottom surface 192. Coupler 190 may extend perpendicularly from bottom surface 176 of top portion 175 to connect top portion 175 with bottom portion 170. Coupler 190 may be made from, for example, plastic or metal. Coupler 190 may have a cylindrical shape and have a size that corresponds to a size and shape of recess 180. In other implementations, coupler 190 may have a different shape and/or top portion 175 may include multiple couplers 190. Bottom surface 192 may reside in a space of recess 180 when top portion 175 is coupled with bottom portion 170. Coupler 190 will be described further below.

Although FIG. 1(e) is a diagram of a side view of exemplary components, in other implementations, top portion 175 of device 100 may include fewer, additional and/or a different components for coupling top portion 175 with bottom portion 170 than those depicted in FIG. 1(e). That is, it is to be understood that there are a multitude of possibilities to couple bottom portion 170 and top portion 175. For example, device 100 may not include a connector, such as coupler 190, to couple bottom portion 170 and top portion 175. As another example, coupler 190 may be disposed on bottom portion 170 instead of top portion 175.

FIG. 1(f) is a diagram illustrating a side view of top portion 175 and bottom portion 170 of device 100. In addition to the components previously described, device 100 may include a resilient pad 194 with a top surface 196.

Resilient pad 194 may be any flexible element, such as a metal or plastic plate having a flexible mechanism attached thereto, such as a spring. In one implementation, bottom surface 192 of coupler 190 may reside on top surface 196 of resilient pad 194. Resilient pad 194 and coupler 190 may be attached to each other. The size and shape of resilient pad 194 may correspond to the size and shape of bottom surface 192 of coupler 190. In this arrangement, resilient pad 194 may provide maneuvering capability for display 150, in addition to the maneuverability provided by the stretching capability of adhesive 182. For example, the flexible mechanism of resilient pad 194 may provide space 136 that exists between bottom surface 176 of top portion 175 and top surface 171 of bottom portion 170. Further, space 135 may provide for a region in which display 150 may be moved. In one instance, a user may freely move display 150 in a 1D, a 2D and/or a 3D fashion, or a combination thereof, and may utilize the navigation capability of display 150 as described herein.

Although FIG. 1(f) illustrates a side view of exemplary components, in other implementations, device 100 may include fewer, additional, and/or different components than the exemplary components depicted in FIG. 1(f). That is, it is to be understood that there are a multitude of possibilities to provide maneuverability of display 150. For example, device 100 may not include a flexible element, such as resilient pad 194, to contribute to the maneuverability of display 150.

Additionally, or alternatively, device 100 may include a movement restrictor, such as a locking mechanism, to regulate the maneuverability of display 150 by locking and unlocking coupler 190. For example, in some instances a user may not need display 150 to move and provide a navigation capability. In such an instance, a user may restrict any movement of display 150 utilizing a locking mechanism to prevent any unnecessary movement of display 150 when operating and/or carrying device 100. However, for example, a stretchable element, such as adhesive 182 may limit the movement of display 150 to a sufficient degree where a movement restrictor may not be necessary. Additionally, or alternatively, device 100 may include logic, such as control unit 220, to disable the navigational capability of display 150. For example, when a user unintentionally moves display 150, disabling logic may prevent an input signal to be generated and/or prevent an input signal to have any effect. Additionally, or alternatively, device 100 may include logic, such as control unit 220 and/or evaluation system 186, that an input signal may be generated only when a value exceeds a threshold value. For example, control unit 220 and/or evaluation system 186 may compare a value associated with a movement to the threshold value.

It is also to be understood that while some exemplary components have been described in reference to bottom portion 170, in other implementations, top portion 175 may include one or more of the exemplary components as described above.

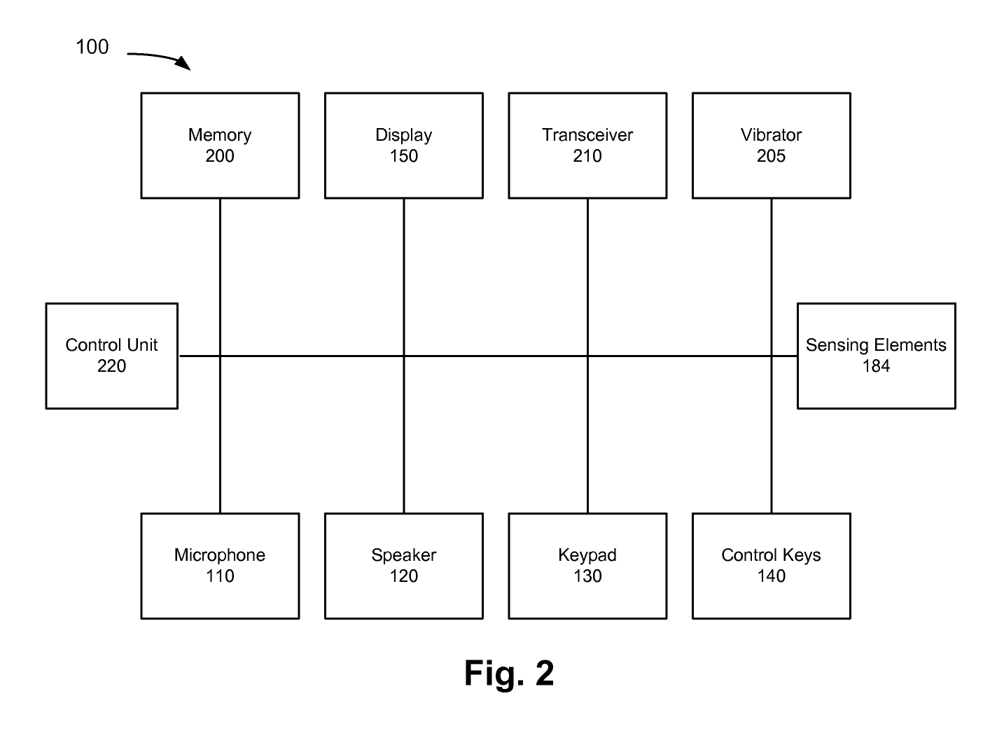

FIG. 2 is a diagram illustrating exemplary internal components of device 100. In addition to the components previously described, device 100 may include a memory 200, a vibrator 205, a transceiver 210, and a control unit 220.

Memory 200 may include any type of storing component capable of storing data and instructions related to the operation and use of device 100. For example, memory 200 may include a memory component, such as a random access memory (RAM), a read only memory (ROM), and/or a programmable read only memory (PROM). Additionally, memory 200 may include a storage component, such as a magnetic storage component (e.g., a hard drive) or other type of computer-readable medium. Memory 200 may also include an external storing component, such as a Universal Serial Bus (USB) memory stick, or a Subscriber Identity Module (SIM) card.

Vibrator 205 may include any component capable of shaking at least a portion of device 100. For example, vibrator 205 may provide a tactile cue to a user associated with an operation of device 100. Transceiver 210 may include any component capable of transmitting and receiving information. For example, transceiver 210 may include a radio circuit that provides wireless communication with a network or another device.

Control unit 220 may include any logic that may interpret and execute instructions, and may control the overall operation of device 100. Control unit 220 may include, for example, a general purpose processor, a microprocessor, a data processor, a co-processor, and/or a network processor. Control unit 220 may access instructions from memory 200, from other components of device 100, and/or from a source external to device 100 (e.g., a network or another device).

Device 100 may include fewer, additional, and/or different components than the exemplary internal components depicted in FIG. 2. One or more internal components of device 100 may include the capabilities of one or more other components of device 100. For example, transceiver 210 and/or control unit 220 may each include their own on-board memory 200.

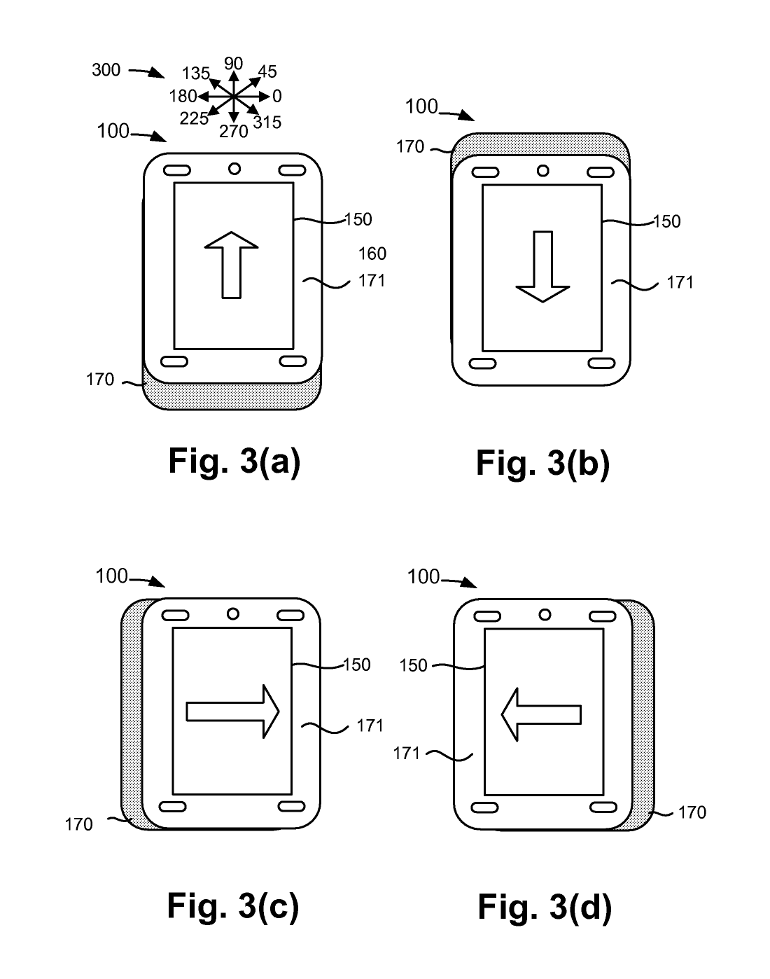

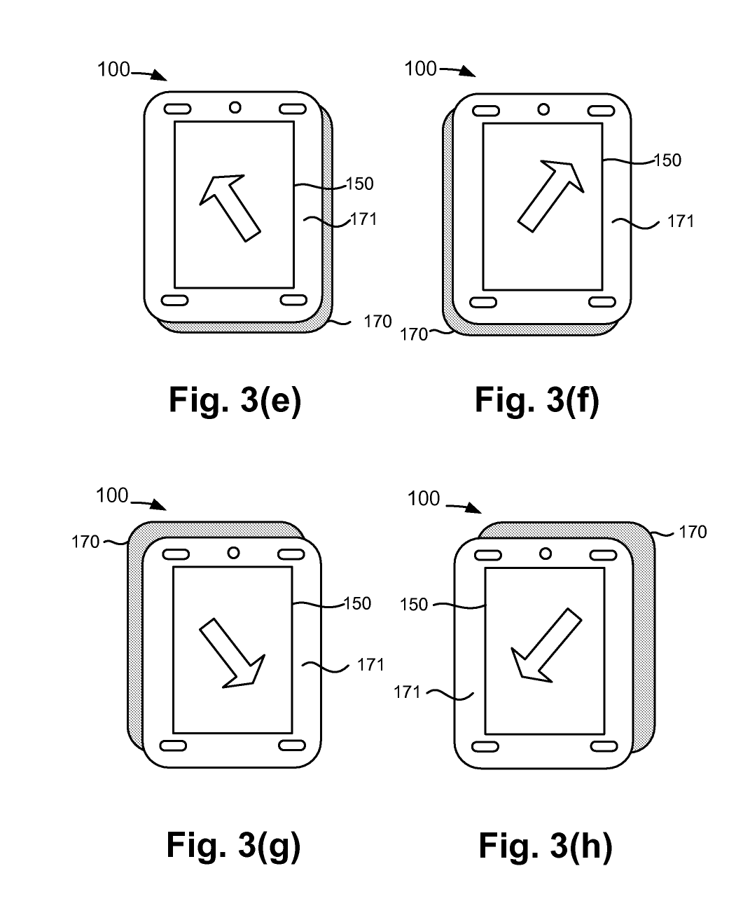

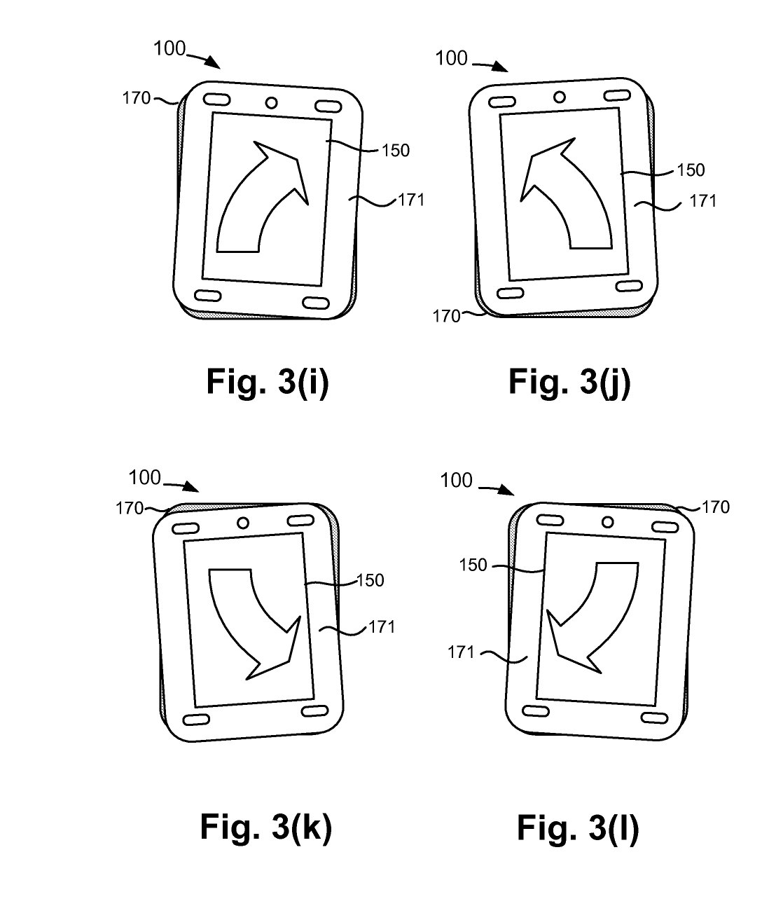

FIG. 3(a)-FIG. 3(l) are diagrams illustrating exemplary movements of a display with navigation capability. Each of the diagrams depicted in FIG. 3(a)-FIG. 3(l) illustrate at least a portion of bottom portion 170, top surface 171 that includes display 150, and an arrow. Each arrow represents an exemplary direction in which display 150 may be maneuvered by a user from a starting position, such as a normal position of display 150. An exemplary directional reference 300 is provided in FIG. 3(a) for purposes of discussion with respect to FIG. 3(a)-FIG. 3(h).

Relative terms, such as forward, back, up, down, etc. may be used herein to describe the direction of the arrow; however, these terms may be different depending on the orientation of device 100. Further, the distance that display 150 may move when display 150 is in, for example, a starting position, to any of the positions illustrated in FIG. 3(a)-FIG. 3(l) may be different than depicted. That is, a movement of display 150 may be relatively small (e.g., not visible to a user) or relatively large (e.g., visible to a user).

As illustrated in FIG. 3(a)-FIG. 3(d), a user may manipulate display 150 in a forward direction (FIG. 3(a)—i.e., direction 90), a backward direction (FIG. 3(b)—i.e., direction 270), a right-side direction (FIG. 3(c)—i.e., direction 0), and a left-side direction (FIG. 3(d)—i.e., direction 180). Further, as illustrated in FIG. 3(e)-FIG. 3(h), a user may manipulate display 150 in a forward/left-side direction (FIG. 3(e)—i.e., direction 135), a forward/right-side direction (FIG. 3(f)—i.e., direction 45), a back/right-side direction (FIG. 3(g)—i.e., direction 315), and a back/left-side direction (FIG. 3(h)—i.e., direction 225).

While FIG. 3(a)-FIG. 3(h) are diagrams that illustrate arrows that are linear, in other instances, a user may manipulate display 150 in a non-linear fashion, such as in a twisting fashion. For example, FIG. 3(i)-FIG. 3(l) illustrate that a user may manipulate display 150 in a twist forward and right direction (FIG. 3(i)), a twist forward and left direction (FIG. 3(j)), a twist back and right direction (FIG. 3(k)), and a twist back and left direction (FIG. 3(l)).

Although FIG. 3(a)-FIG. 3(l) are diagrams illustrating exemplary maneuvers, in other instances, display 150 may maneuver in still other directions not depicted. That is, display 150 may maneuver in any manner of a 1D space, in any manner of a 2D space, as well as any manner of a 3D space.

As will be described below, any of the manipulations of display 150 may produce an input signal. It is to be understood, however, that when display moves from, for example, a position depicted in FIG. 3(a)-FIG. 3(l) to a starting position, such as a normal position of display 150, that an input signal may not be produced.

As illustrated, a user of device 100 with display 150 having navigation capability may be afforded numerous possibilities to interact with device 100 and/or devices external to device 100. In other implementations of device 100, display 150 may not be able to move in any 1D, 2D, or 3D fashion. For example, device 100 may provide display 150 to only move in any 1D fashion, but not in a 2D fashion or a 3D fashion. In other examples, device 100 may include display 150 that is capable of only moving in a 1D and a 2D fashion, but not in a 3D fashion. Still further, in other examples, device 100 may include display 150 that is capable of only moving in a 1D fashion (e.g., up and back), but not any direction of a 1D fashion (e.g., a direction perpendicular to a surface of device 100). Thus, in other configurations and implementations of device 100, the maneuverability of display 150 may be different and/or limited.

Still further, as described above, other components of device 100 may include navigation capability. For example, keypad 130 may include the navigation capability as described herein. That is, for example, display 150 may not include navigation capability, but keypad 130 may include navigation capability. Even further, in other implementations, multiple components of device 100 may include the navigation capability as described herein. For example, an input device, such as keypad 130 or other input buttons, in addition to display 150 may include the navigation capability as described herein. Thus, various devices 100 having numerous configurations may be contemplated, in which display 150 may include navigation capability, components other than display 150 may include navigation capability, or other components in addition to display 150 may include the navigation capability as described herein.

It is also to be understood that device 100 may include display 150 in alternate orientations. For example, device 100 may include display 150 in a portrait, landscape, or a combination thereof orientation, and that display 150 in any of these orientations may include navigation capability.

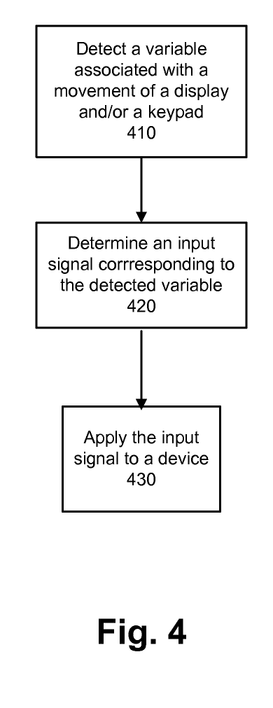

FIG. 4 is a flow diagram illustrating exemplary operations associated with the exemplary device. In block 410, device 100 may detect a variable associated with a movement of display 150 and/or an input device, such as keypad 130. For example, sensing elements 184 may detect a movement of display 150 and/or any variable associated with the movement (e.g., velocity, acceleration, position, force, etc.). In other instances, a manipulation of display 150 may not result in a movement of display 150. For example, sensing elements 184 may detect, for example, force.

In block 420, device 100 may determine an input signal corresponding to the detected variable. For example, evaluation system 186 and/or control unit 220 may determine how display 150 is moved (e.g., direction of movement) or how display 150 is manipulated (e.g., a force not resulting in a movement), and may determine a corresponding input signal associated with the movement or manipulation based on information from sensing elements 184. In one implementation, evaluation system 186 and/or control unit 220 may operate in conjunction with, for example, various drivers and/or the operating system of device 100 to determine the input signal.

In block 430, device 100 may apply the input signal to a device. The device may be device 100 or a device external to device 100. For example, the input signal may be associated with display 150 of device. For example, the input signal may be a cursor function, a selection function, a scrolling function, turning a page function, a zoom-in function, a zoom-out function, a rotate function, a resize function, etc. that is displayed on display 150. In another example, the input signal may be used to output an auditory and/or a tactile cue to a user of device 100. For example, various sounds may be associated with the input signal to indicate to a user that the display is moved in a certain manner (e.g., “Up”, “Down”, “Twist”, etc.), or that a particular function has occurred (e.g., “Highlighted”, “Scroll”, “Turn Page”, etc.). For example, device 100 may output an auditory cue through speaker 120. In still other examples, the input signal may provide for a vibration to occur that may allow a user of device 100, for example, to confirm that display 150 is moved. For example, device 100 may output a tactile cue through vibrator 205.

In another example, the input signal may be used to control another device, such as a remote control vehicle (e.g., a car, airplane or helicopter) or a security camera. For example, a user may steer the vehicle or point a security camera in a certain direction by moving display 150. In another example, the input signal may be associated with an external display. For example, a user may be running a game on device 100 that is displayed on a television. A user may control, for example, a character in the game by moving or manipulating display 150 of device 100.

### EXAMPLES

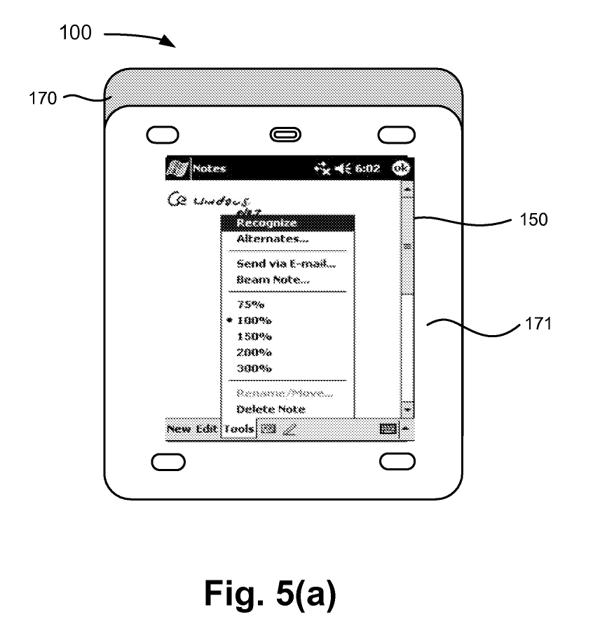

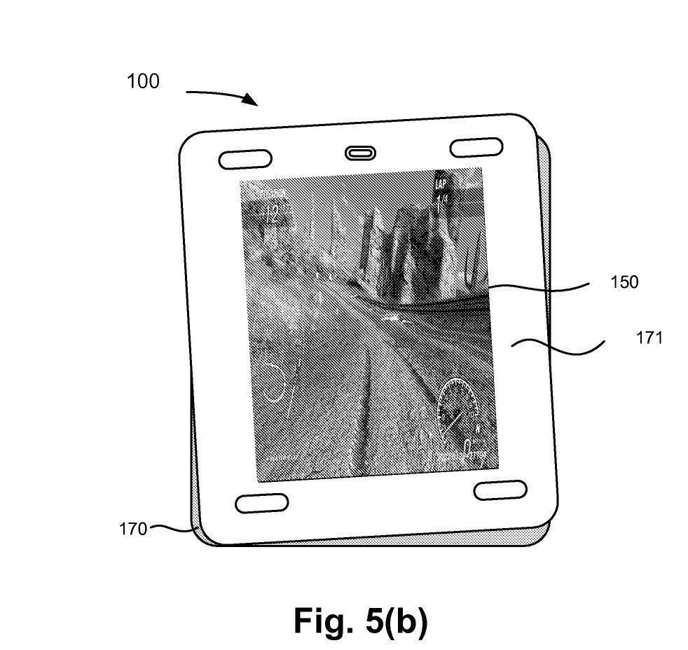

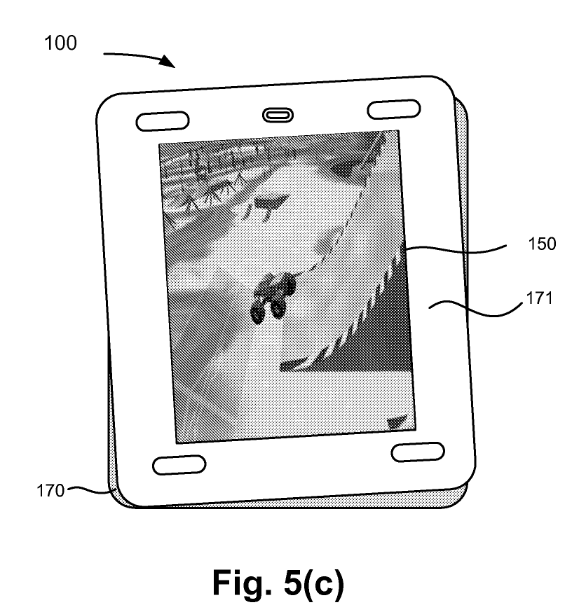

FIG. 5(a)-FIG. 5(c) are diagrams illustrating exemplary operations of display 150. In other impleentations, components other than display 150 may include navigation capability, or components in addition to display 150 may include navigation capability. A discussion relating to the operation of device 100 will be provided with reference to FIG. 5(a). Device 100 may operate in a similar manner in reference to FIG. 5(b) and FIG. 5(c).

In FIG. 5(a), a user of device 100 may be using the application “Notes” of Windows Mobile 2003. As illustrated, the user may access a menu system. The user may cursor through the menu options (e.g., Recognize, Alternates, etc.) by manipulating display 150 in a back direction. When the user moves top surface 171 in a back direction, adhesive element 182 may stretch. Sensing elements 184 may detect the movement of display 150 and output data signals to evaluation system 186 on data lines 188. Evaluation system 186 may determine the occurrence of the movement and/or direction of the movement based on the received data, and output a signal to control unit 220. Control unit 220 may output a signal (i.e., an input signal) to display 150 so that the movement of display 150 operates to cursor through the menu system.

In FIG. 5(b), a user of device 100 may be playing a game that involves driving a truck. As illustrated, the user may twist display 150 to drive the truck. While both in FIG. 5(a) and FIG. 5(b), the direction in which display 150 was moved corresponded to a direction of the navigation function. In other instances, the navigation function may be directionless. For example, in FIG. 5(c), a user of device 100 may be playing a different game that involves driving a 4-wheeler. In this game, however, the user may manipulate display 150 in a 3D fashion. That is, the user may twist display 150 to steer the truck, and may either press down or not press down display 150 for purposes of controlling the speed of the truck.

As previously mentioned and illustrated above, display 150 with navigation capability may provide a user with a new array of functionality not otherwise provided in other devices. For example, in FIG. 5(a), the user may cursor through a menu by moving display 150 in a backward direction, and be able to select a menu option (e.g., Recognize) by pressing display 150 down. In other implementations, depending on a mapping of a manipulation and corresponding application, the user may press display 150 in a downward direction to perform a “zoom” function. Accordingly, device 100 with navigation capability provides a user with unique input capabilities associated with the manipulation of display 150.

In another exemplary embodiment of device 100, a user may manipulate display 150 without moving display 150. For example, sensing elements 184 may detect force and/or pressure applied by a user on display 150 that does not result in moving display 150. The detected force and/or pressure may be determined by evaluation system 186 in order to provide the navigation capability as described herein.

The foregoing description of implementations provides illustration, but is not intended to be exhaustive or to limit the implementations to the precise form disclosed. Modifications and variations are possible in light of the above teachings or may be acquired from practice of the teachings.

It should be emphasized that the term “comprises” or “comprising” when used in the specification is taken to specify the presence of stated features, integers, steps, or components but does not preclude the presence or addition of one or more other features, integers, steps, components, or groups thereof.

In addition, while a series of processes and/or acts have been described herein, the order of the processes and/or acts may be modified in other implementations. Further, non-dependent processes and/or acts may be performed in parallel.

It will be apparent that aspects described herein may be implemented in many different forms of software, firmware, and hardware in the implementations illustrated in the figures. The actual software code or specialized control hardware used to implement aspects does not limit the invention. Thus, the operation and behavior of the aspects were described without reference to the specific software code—it being understood that software and control hardware can be designed to implement the aspects based on the description herein.

No element, act, or instruction used in the present application should be construed as critical or essential to the implementations described herein unless explicitly described as such. Also, as used herein, the article “a”, “an”, and “the” are intended to include one or more items. Where only one item is intended, the term “one” or similar language is used. Further, the phrase “based on” is intended to mean “based, at least in part, on” unless explicitly stated otherwise.

The term “connect” and variations thereof (e.g., connected or connection) may be direct or indirect. As used herein, the term “and/or” includes any and all combinations of one or more of the associated list items.

Even though particular combinations of features are recited in the claims and/or disclosed in the specification, these combinations are not intended to limit the invention. In fact, many of these features may be combined in ways not specifically recited in the claims and/or disclosed in the specification.

What is claimed is:

1. A portable device, comprising:
a display;
a component capable of moving in a one dimensional, a two dimensional, or a three dimensional fashion;
logic to detect a variable associated with a movement of the component;
logic to generate a signal corresponding to the detected variable; and
logic to utilize the signal in the portable device or output the signal to an external device,
wherein the component includes at least one of the display or one or more keys, and wherein the component capable of moving in the one dimensional fashion is capable of moving in a direction other than a direction substantially perpendicular to a surface of the portable device that includes the component.

2. The portable device of claim 1, wherein the portable device includes wireless telephone capability.

3. The portable device of claim 1, further comprising a flexible member connected to the component to provide maneuverability in the one dimensional, the two dimensional or the three dimensional fashion.

4. The portable device of claim 1, wherein the variable includes at least one of force, pressure, motion, position, velocity, or acceleration.

5. The portable device of claim 1, wherein the portable device is at least one of a candybar style, a flip style, a slider style, a jackknife style, a tablet style, a sandwich style, or a combination thereof.

6. The portable device of claim 1, further comprising:
logic to disable at least one of the logic to detect, the logic to generate, or the logic to utilize.

7. The portable device of claim 1, wherein the logic to utilize the signal comprises:
logic to map the signal to a function associated with an application running on the portable device.

8. The portable device of claim 7, wherein the function includes at least one of a cursor function, a selection function, a scrolling function, a turning a page function, a zoom-in function, a zoom-out function, a rotate function, or a resize function.

9. The portable device of claim 1, further comprising:
a speaker; and
a vibration system,
wherein the logic to utilize the signal comprises logic to map the signal to at least one of the speaker to output an auditory cue or to the vibration system to output a tactile cue.

10. The portable device of claim 1, wherein the display is a touchscreen.

11. The portable device of claim 1, wherein the logic to generate a signal comprises:
logic to compare a value associated with the movement to a threshold value,
wherein when the value exceeds the threshold value, the logic to generate generates the signal.

12. A portable device, comprising:
a display;
a component capable of being manipulated in a one dimensional, a two dimensional, or a three dimensional fashion;
logic to detect the manipulation of the component;
logic to generate a signal corresponding to the detected manipulation; and
logic to associate the signal with a function to be utilized in the portable device or output to an external device,
wherein the component includes at least one of the display or a keypad, and wherein the component capable of being manipulated in the one dimensional fashion is capable of being manipulated in a direction other than a direction substantially perpendicular to a surface of the portable device that includes the component.

13. The portable device of claim 11, wherein the logic to detect the manipulation comprises:
logic to detect pressure.

14. A method, comprising:
moving in a one dimensional, a two dimensional or a three dimensional fashion a component of a device having a display;
detecting a variable associated with the movement;
generating a signal corresponding to the detected variable; and
applying the signal to the device or to an external device,
wherein the component includes at least one of the display or one or more keys, and wherein the moving in the one dimensional fashion is moving in a direction other than a direction substantially perpendicular to a surface of the device that includes the component.

15. The method of claim 14, wherein the detecting the variable comprises:
detecting at least one of force, pressure, motion, position, velocity, or acceleration.

16. The method of claim 14, wherein the applying the signal to the device comprises:
providing a function that is displayable on the display.

17. The method of claim 14, wherein the applying the signal to the external device comprises:
providing a function that is displayable on an external display, wherein a direction associated with the moving of the component corresponds the function.

18. The method of claim 14, wherein the generating the signal corresponding to the detected variable comprises:
determining whether a value of the variable associated with the movement of the component exceeds a threshold value.

19. The method of claim 14, wherein the generating the signal corresponding to the detected variable comprises:
mapping the signal to a function associated with an application running on the device; and
displaying the function on the display.

20. The method of claim 14, wherein the moving in the two dimensional or the three dimensional fashion comprises:
moving the component in a twisting manner.

21. A device, comprising:
means for displaying visual information;
means for providing the means for displaying to be movable in a one dimensional, a two dimensional, or a three dimensional fashion;
means for detecting a variable associated with a movement of the means for displaying;
means for providing a function that corresponds to the detected variable, wherein the function is displayable on the means for displaying.
